(19) United States
(12) Patent Application Publication
(10) Pub. No.: US 2006/0292725 A1
(43) Pub. Date: Dec. 28, 2006

(54) Method for manufacturing device having optical semiconductor element

(75) Inventors: Tsutomu Fukai, Hong Kong (CN); Masahiro Onishi, Hong Kong (CN)

Correspondence Address: NIXON & VANDERHYE, PC, 901 NORTH GLEBE ROAD, 11TH FLOOR, ARLINGTON, VA, 22203, US

(73) Assignee: SAE Magnetics (H.K.) Ltd., Hong Kong (CN)

(21) Appl. No.: 11/476,201

(22) Filed: Jun. 28, 2006

(30) Foreign Application Priority Data
Jun. 28, 2005 (JP) 2005-188303

(51) Int. Cl. H01L 21/00; H01L 21/30

(52) U.S. Cl. 438/29; 438/455

(57) ABSTRACT

The invention provides a method of forming a device having an optical semiconductor element by bonding a cover body, which can cover the optical semiconductor element, to a head portion having the optical semiconductor element. The method comprises the steps of: a short circuit step of shorting terminals of the optical semiconductor with each other (S3); a bonding step of bonding the head portion and the cover body by welding (S5); and a step of eliminating short between the shorted terminals (S6). By method of the invention, electric influence applied to the optical semiconductor mounted on the head portion during welding process is prevented.

### FIELD OF THE INVENTION

The invention relates to a method for manufacturing device having an optical semiconductor element, and more specifically, the invention relates to a method for bonding a head portion, which has an optical semiconductor element provided therein, and a cover body that covers the optical semiconductor element.

### BACKGROUND OF THE INVENTION

Optical modules are widely used in fields such as optical communication or data processing via optical signal. An optical module comprises a device with an optical semiconductor for example a light-emitting element (laser diode) or a light-receiving element (photodiode) provided therein, an optical component such as a lens and an enclosure for supporting and positioning components such as a ferrule used for a fiber. The device having an optical semiconductor element takes various structures. A device having a structure, in which, a head portion having an optical semiconductor and a cover body to cover the semiconductor are bonded together, has been disclosed. Here, the cover body is provided for protecting the optical semiconductor element, or used as a reflective surface to reflect light, which is emitted from the light-emitting element, to the light-receiving element. In addition, as an exemplary example, the head portion is mainly made of material such as SPC or kovar (KOV) for reducing influence generated by heat radiation of itself and improving reliability. To prevent leakage of the light from circumference of the cover body, the cover body needs to have designed intensity, light-reflecting performance and leakage-preventing performance; therefore, the cover body is primarily constructed by metal. In this case and generally speaking, semi-transparent mirror or lens is attached on the cover body at central location thereof for providing a light passing through path, and coaxiality between the head portion and the cover body is also important.

The combination portion of the device having an optical semiconductor is formed generally by kinds of welding manners. In general, resistance welding or laser welding is used as a welding method. In a resistance welding process, the part to be welded is disposed between two electrodes of different voltages; then a current of high energy passes through the part and heat is thus generated when the part contacts the electrodes; then the heat makes the part melted and welded. In a laser welding process, laser of high energy is utilized to be irradiated to the part and then makes the part melted, thus achieving welding. The above conventional technology is disclosed in patent reference 1, in which a resistance welding is used to combine the head portion and the cover body, and a projection welding method is used to combine the cover body and a barrel used for receiving a ferrule.

For assuring coaxiality of the head portion and the cover body, as well as combination of the head portion and the cover body, a further technology is disclosed as follows. FIG. 7 shows a schematic side view of a conventional device with an optical semiconductor element incorporated therein. The device 1 comprises a head portion 2 as shown in FIG. 7(b) and a cover body 3 as shown in FIG. 7(a), and the head portion 2 has a light-emitting element 22 and a light-receiving element 23 disposed on one side of a base end 21 thereof. As an example, the light-emitting element 22 may be a laser diode, and as an example, the light-receiving element 23 may be a photodiode. The light-receiving element 23 is used to indicate light irradiation of the light-emitting element 22. In addition, terminals 24a, 24b for controlling irradiation of the light-emitting element 22, and terminals 25a, 25b for controlling operation of the light-receiving element 23, are extended from the opposite side of the base end 21 respectively. As an example, the terminals may have a length of approximately 2 cm. A metal flange (referred to as a head portion flange 26 hereinafter) forms the circumference of the base end 21. The cover body 3 comprises a case portion 31 and a base portion 32, and a flange (referred to as a cover body flange 33) forms the circumference of the base portion 32. The cover body 3 is metallic, and a semitransparent mirror or lens (not shown) is attached at a location adjacent the central portion of the case portion 31 for insuring optical path. The head portion flange 26 of the head portion 2 and the cover body flange 33 of the cover body 3 are bonded together by resistance welding manner, thereby forming a device 1 having an optical semiconductor element provided therein, as shown in FIG. 7(c).

A conventional bonding method for bonding a head portion and a cover body of structure described above is illustrated below. FIG. 8 schematically shows the bonding method for bonding the head portion and the cover body shown in FIG. 7. Firstly, as shown in FIG. 8(a), the head portion 2 is received in a receptacle 4. Then, a first electrode 5 of barrel shape is mounted around the receptacle 4. In this situation, since the head portion flange 26, which is disposed at a front-end portion of the head portion 2, has a diameter larger than the inner diameter of the first electrode 5, the head portion flange 26 is held on a front end portion of the first electrode 5, as shown in FIG. 8(b). In addition, a second electrode 7 is disposed in the cover body 3. Similarly, the cover body flange 33 is held on a front-end portion of the second electrode 7. Next, as shown in FIG. 8(c), the first electrode 5 and the second electrode 7 are approaching toward each other so that the head portion flange 26 engages the cover body flange 33. Under this condition, a current passes through the electrodes 5, 7, and accordingly, the head portion flange 26 and the cover body flange 33 are combined each other by the resistance welding manner. Next, as shown in FIG. 8(d), the electrodes 5, 7 and the receptacle 4 are taken out, thus forming the device 1 having an optical semiconductor incorporated therein.

Patent reference 1: Japanese patent application publication gazette NO. 6-291369.

When fabricating the device 1 having an optical semiconductor using the foregoing method, a big current (from several kA to tens of kA) passes through the two electrodes during resistance welding process. However, since the terminals 24a, 24b of the light-emitting element 22 and the terminals 25a, 25b of the light-receiving element 23 are in an open state, a small buffering current (electric charge) flows from the electrodes into the optical semiconductor such as the light-emitting element or light-receiving element, and is accumulated, thus affecting these elements. Namely, due to influence of electric characteristic in welding process, these semiconductor elements are changed in nature, and accordingly, the performance and reliability thereof are affected. In addition, yields of the product are also affected.

### SUMMARY OF THE INVENTION

One object of the invention is to provide a method for manufacturing a device having an optical semiconductor formed therein. By this method, electric influence, which is generated during welding process and which applies on the optical semiconductor mounted on the head portion, is prevented.

The invention provide a method of forming a device having an optical semiconductor element by bonding a cover body, which can cover the optical semiconductor element, to a head portion having the optical semiconductor element. The method comprises a short circuit step of shorting terminals of the optical semiconductor with each other; a bonding step of bonding the head portion and the cover body by welding; and a step of eliminating short between the shorted terminals.

As illustrated above, in the invention, the head portion and the cover body are welded together after the terminals of the optical semiconductor element are shorted with each other; accordingly, since the terminals are shorted with each other, even a high voltage is applied on the optical semiconductor element during welding process, and consequently even charge is induced at one end of the optical semiconductor element, the charge thus generated can still be conducted to the other end thereof. More specifically, the charge will not accumulate at the ends and inside the optical semiconductor, thus reducing possibility of the optical semiconductor itself being affected by the charge.

Preferably, the short circuit step comprises a step of electrically connecting respective terminals to electrically conductive connection terminals; and a connection terminal short circuit step of shorting the connection terminals with each other.

Preferably, the connection terminal short circuit step comprises a step of connecting the connection terminals with each other by welding and a step of grounding the connection terminals.

Preferably, the short circuit step comprises a step of holding the number of connection terminals, holding the head portion on a receptacle that is electrically connected with the connection terminals, and at the same time, electrically coupling a first electrode, which is electrically connected with the receptacle, to a head flange disposed at a front end of the head portion; and a step of electrically connecting a cover flange disposed at a front end of the cover body to a second electrode. In the bonding step, the head flange and the cover flange are sealed together, and a current passes through the first and second electrodes, thus making the head flange and the cover flange welded together.

Preferably, in the short circuit step, the terminals are held together by a clip or are held together by welding.

Preferably, in the short circuit step, the terminals are inserted into respective holes formed in a metal body, thus making the terminals shorted.

Preferably, the optical semiconductor comprises a light-emitting element and a light-receiving element. In the short circuit step, the terminals of the light-emitting element and light-receiving element are all shorted with each other.

Preferably, the optical semiconductor comprises a light-emitting element and a light-receiving element; and in the short circuit step, the terminals of the light-receiving element are shorted with each other when the light-emitting element irradiates light.

As illustrated above, according to the invention, since the ends of the optical semiconductor element are shorted with each other prior to welding process, the charge induced during the welding process will not accumulate at the ends and inside the optical semiconductor element, thereby reducing impact on the optical semiconductor element caused by the charge. As illustrated above, the invention provides a method of forming a device having an optical semiconductor element provided therein. By this method, electric influence applied on the optical semiconductor mounted on the head portion during welding process is prevented.

### BRIEF DESCRIPTION OF THE DRAWINGS

The accompanying drawings facilitate an understanding of the various embodiments of this invention. In such drawings:

FIG. 1 shows cross-sectional views of a head portion and a receptacle according to the invention;

FIG. 2 shows a flowchart illustrating a method for manufacturing a device having an optical semiconductor element;

FIG. 3 shows a cross-sectional view of the head portion and the receptacle shown in FIG. 1 in an assembled state;

FIG. 4 shows a cross-sectional view of the head portion and the cover body in an assembled state;

FIG. 5 shows a conceptual view illustrating principle of resistance welding;

FIG. 6 schematically illustrates terminal connecting structure of the head portion of the embodiment and conventional technology respectively;

FIG. 7 shows a side view of a device having an optical semiconductor provided therein; and

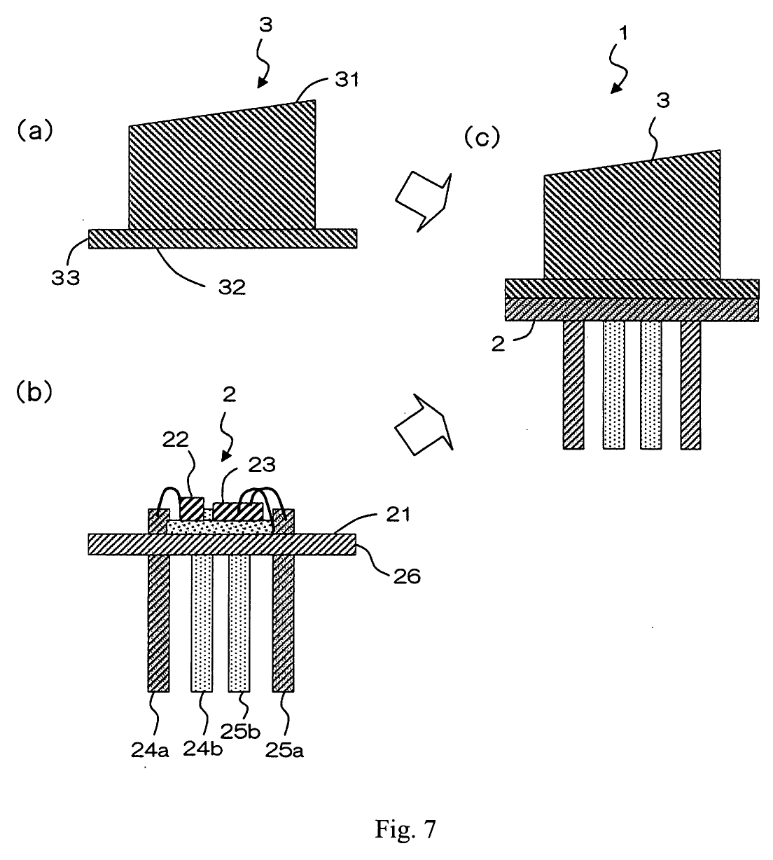

FIG. 8 shows a schematic view illustrating a method of bonding the head portion and the cover body shown in FIG. 7.

### DETAILED DESCRIPTION OF ILLUSTRATED EMBODIMENTS

Now, various embodiments of the invention will be described in conjunction with the drawings. A device having an optical semiconductor element provided therein may be used in the invention. The device includes a head portion with a light-emitting element and a light-receiving element formed therein, and a cover body that is combined with the head portion and that can cover the optical semiconductor element.

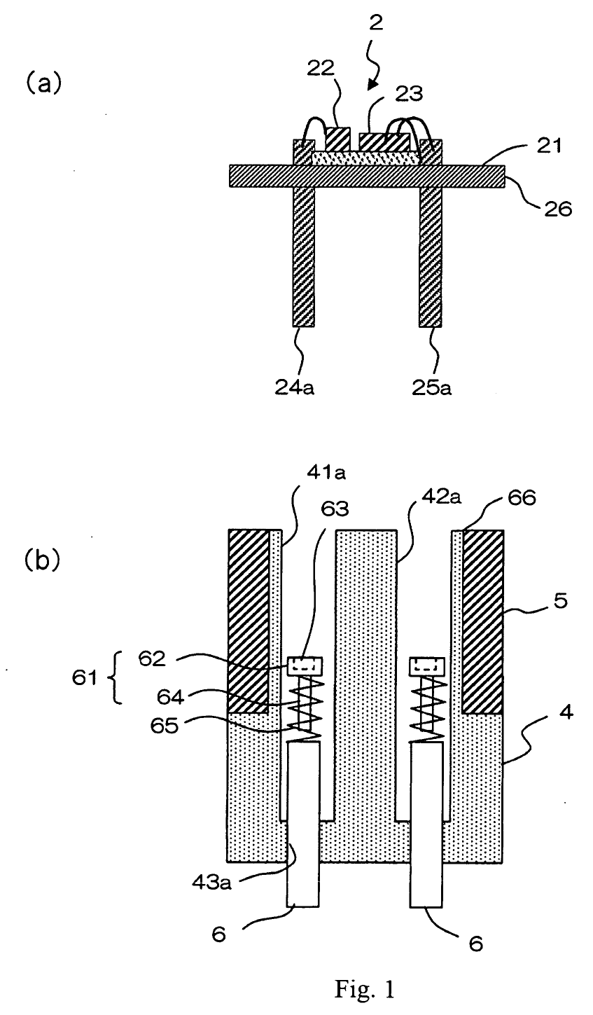

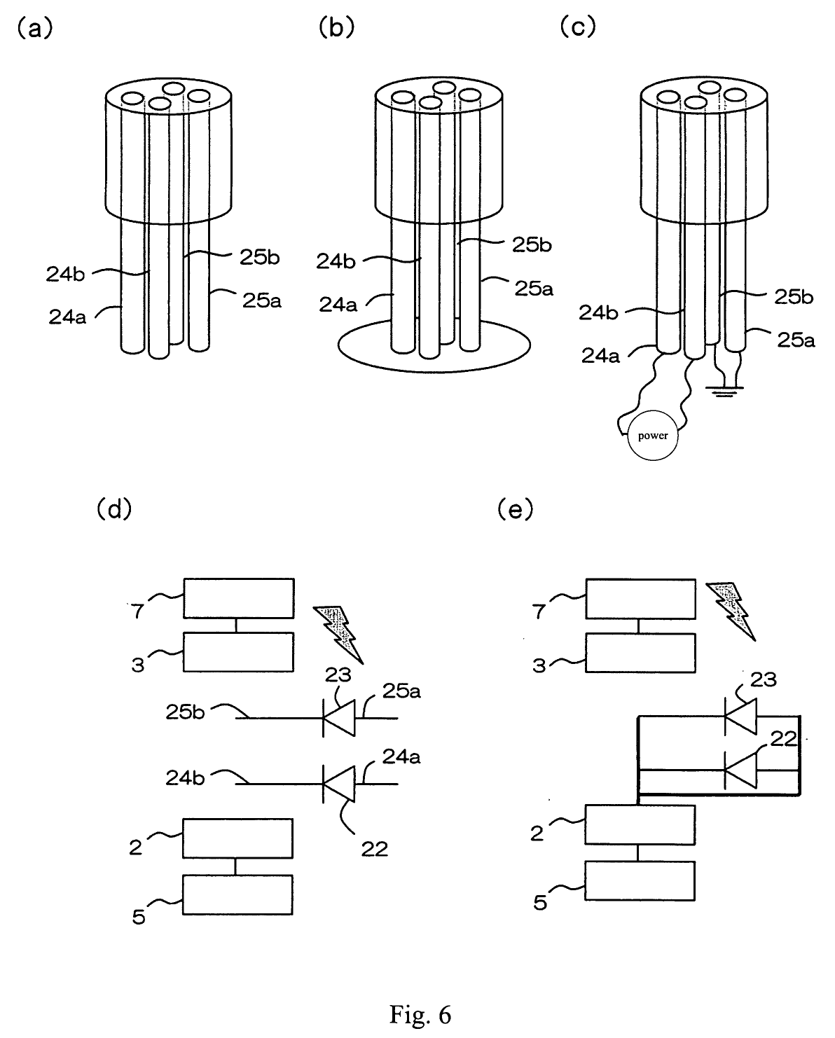

FIG. 1 shows cross-sectional views of a head portion and a receptacle according to the invention. The head portion shown in FIG. 1(a) has the same structure as that shown in FIG. 6, and accordingly detailed description thereof may be found in content in background. It is noted that only terminals 24a, 25a are shown in FIG. 1; however, there are terminals 24b and 25b (not shown) that are disposed behind the terminals 24a, 25a.

FIG. 1(b) shows a cross-sectional view of a receptacle. The receptacle 4 is mainly of a cylindrical shape and, a diameter-reduced portion 66, which has a reduced outer diameter, is formed at an opening 41a of the receptacle 4. A barrel-shaped first electrode 5 is imbedded into the diameter-reduced portion 66. The receptacle 4 has an opening 41a, 42a for receiving the terminals 24a, 25a of the head portion 2 respectively. Similarly, the receptacle 4 also has an opening 41b, 42b for receiving the terminals 24b, 25b (not shown) respectively. The following description will be directed to the terminal 24a and corresponding opening 41a, and description related to the terminals 24b, 25a, 25b and openings 41b, 42a, 42b is similar. An electrically conductive connection terminal 6 made of non-metal material is disposed in the opening 41a. The terminal 6 passes through an opening 43a formed at the lower end of the receptacle 4 and extends from outside of the receptacle 4. The receptacle 4 is contacted with the opening 43a at the lower end of the receptacle 4, and electrically connected with the opening 43a. By this manner, the receptacle 4 holds number of the connection terminals 6 and electrically coupled with the connection terminals 6.

A pin 61 is positioned in the opening 41a and above the terminal 6. The pin 61 comprises a pin head portion 62 having a recess portion 63 formed thereon for receiving the terminals 24a and a rod 64. The recess portion 63 may have a shape consistent with that of the front-end portion of the terminal 24a, and the front-end portion of the terminal 24a may be of a cylinder, cone, frustum or other shape. A spring 65, which surrounds and extends along the rod 64, is provided on the pin head portion 62.

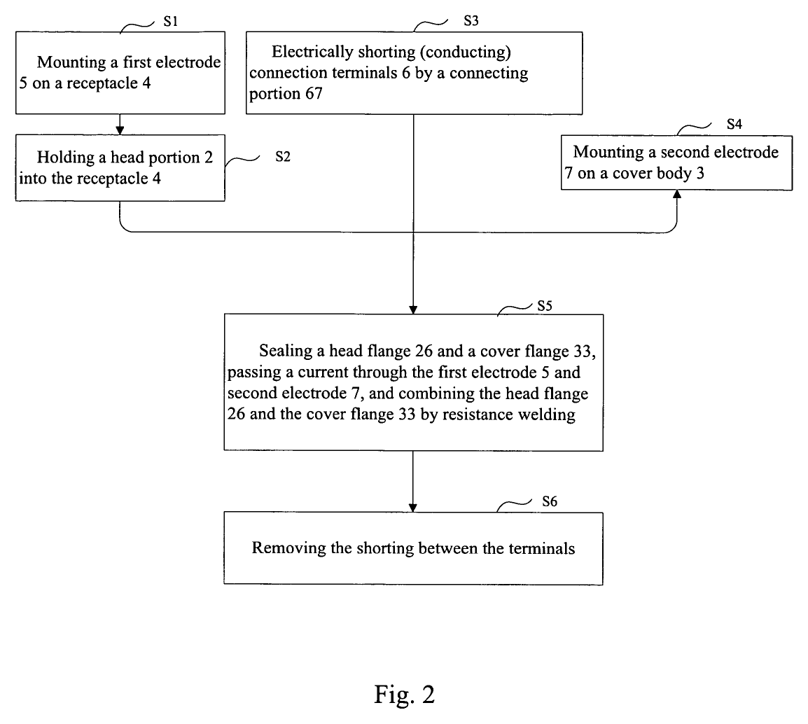

FIG. 2 shows a flowchart illustrating a method for manufacturing a device having an optical semiconductor element. Next, the method for manufacturing a device having an optical semiconductor element is illustrated in conjunction with FIG. 2.

(Step 1) A first electrode 5 is mounted on the receptacle 4. Both the receptacle 4 and the first electrode 5 are electrically conductive, and they are electrically connected with each other. However, a receptacle 4 having a first electrode 5 provided thereon in advance may also be utilized, and in this case, the step 1 may be omitted.

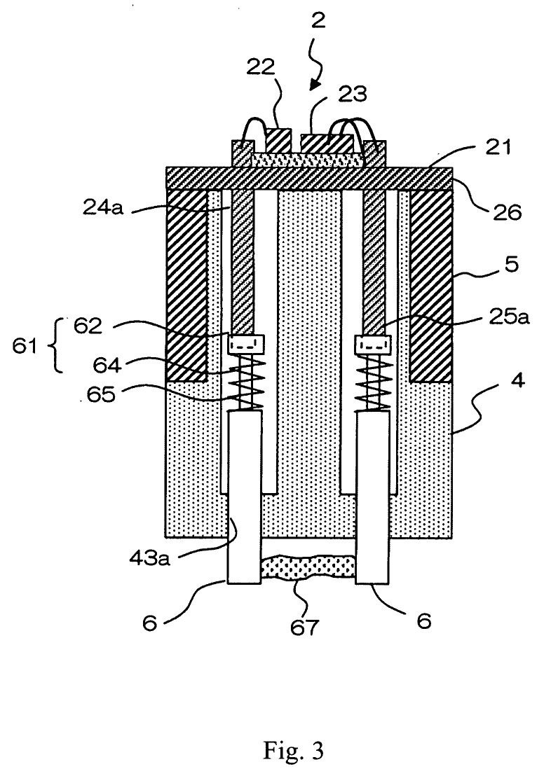

(Step 2) The head portion 2 is contained in the receptacle 4. Namely, they are changed from a state shown in FIG. 1 to a state shown in FIG. 3. More specifically, the terminals 24a, 24b, 25a and 25b of the head portion 2 are inserted into the openings 41a, 41b, 42a and 42b of the receptacle 4. Next, the terminal 24a and opening 41a are taken as an example for description purpose. The distal end of the terminal 42a is received in the recess portion 63 of the pin head portion 62 of the pin 61, and the pin 61 is pressed downwards. Accordingly, the spring 65 is compressed, and the rod 64 of the pin 61 contacts the connection terminal 6. Since the pin 61 is conductive, the terminal 24a is electrically connected with the connection terminal 6. Moreover, when the head portion 2 is mounted in the receptacle 4, front end of the first electrode 5 will contact with the head flange 26 disposed at front end of the head portion 2, thus electrically connecting the first electrode 5 and the head portion 2.

(Step 3) The connection terminals 6 are electrically connected with each other through a connecting portion 67. Preferably, the connecting portion 67 is formed by resistance-welding method for enhancing operability and reducing conduct resistance. It is preferred that the connecting portion 67 is welded in a manner surrounding the adjacent connection terminals 6 in turn. By this manner, all the terminals 24a, 24b, 25a, and 25b of the light-emitting element 22 and the light-receiving element 23 are shorted between each other. Here, a receptacle 4 with a connecting portion 67 formed thereon in advance may also be used, and in this situation, the step may be omitted.

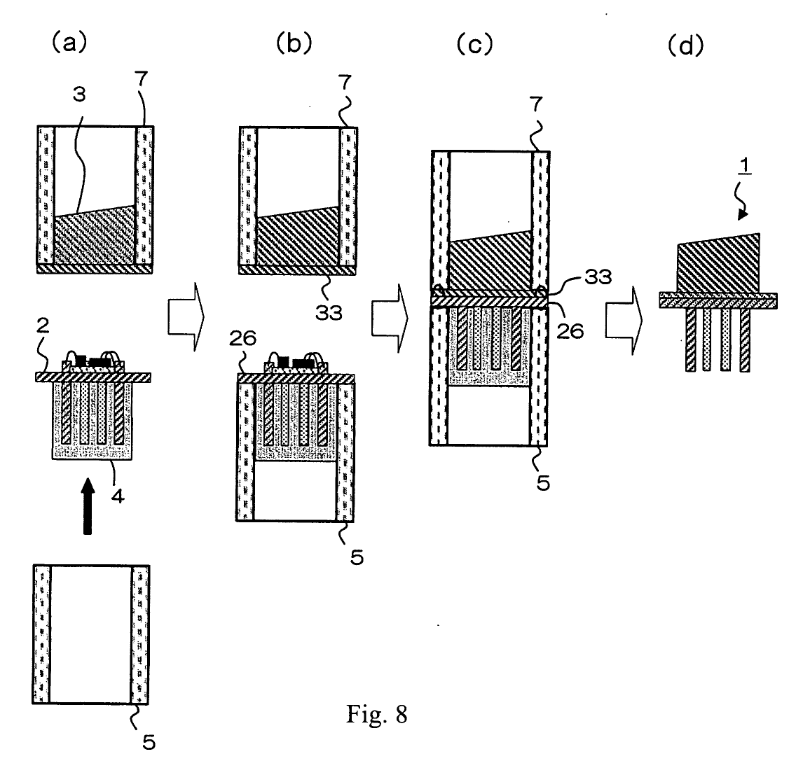

(Step 4) A second electrode 7 is mounted on the cover body 3. The mounting method is shown-in FIGS. 8(a) and 8(b). Since diameter of the cover flange 33, which is disposed on the front end of the cover body 3, is larger than inner diameter of the barrel-shaped electrode 7, the cover body contacts the front end of the second electrode 7 and is held by the second electrode 7, and the second electrode 7 is electrically connected with the cover body flange 33.

In addition, it is necessary to regard the step 1 and step 2 as a serial of operations and perform them sequentially; however, since the step 3 and step 4 are independent from the step 1 and step2, the steps 1, 2, 3 and 4 can be performed according to any sequence.

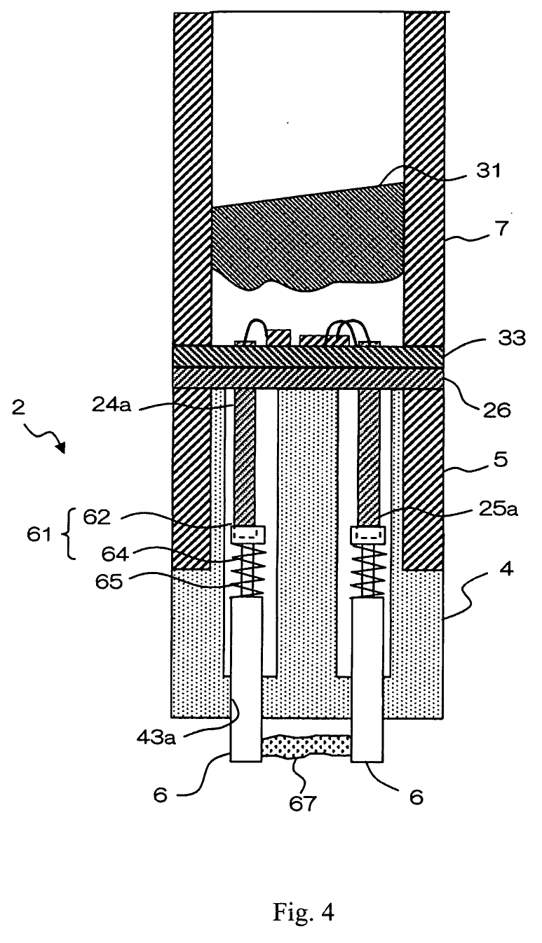

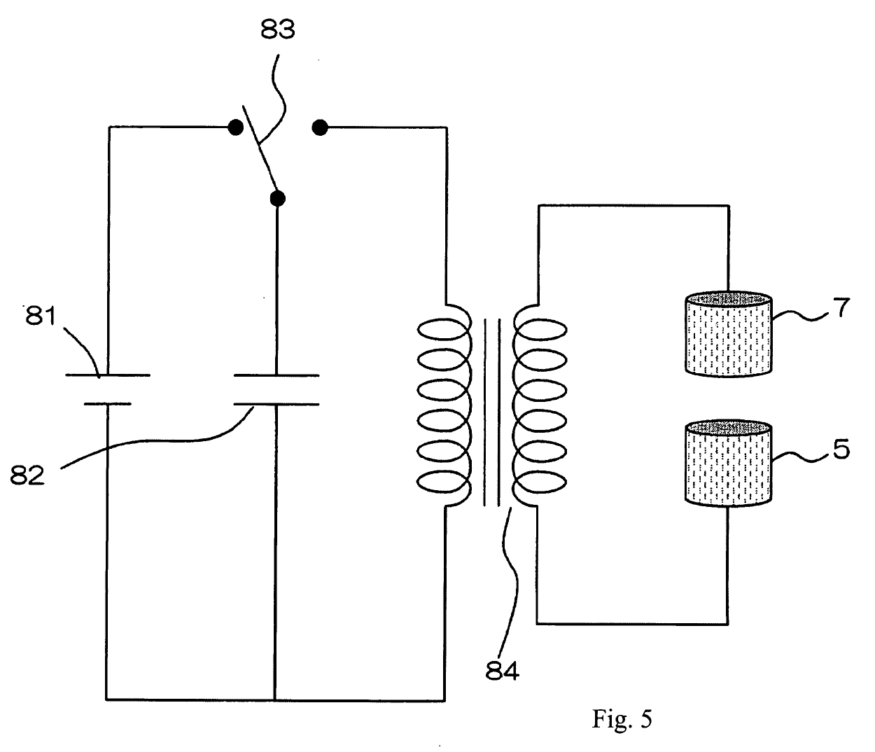

(Step 5) As shown in FIG. 4, the head flange 26 and the cover flange 33 are sealed together, a current passes through the first electrode 5 and the second electrode 7, and the head flange 26 is bonded with the cover flange 33 by resistance welding. FIG. 5 shows principle of the resistance welding process. At the first, as the parts to be welded, the head portion 2 and the cover body 3 are mounted on the first electrode 5 and the second electrode 7 respectively. Then, a switch 83 is switched to a power 81 so that the power 81 works and a capacitor 82 of big capacitance is charged to a regulated voltage. After completion of charge, the switch 83 is switched such that a current is supplied to a rectification transformer 84. After that, a secondary current rectified by the rectification transformer 84 is supplied to the electrodes 5 and 7, thus making the head flange 26 and the cover flange 33 bonded together.

(Step 6) Then, by removing the electrodes 5, 7 and the receptacle 4, electrical shorting of the terminals is eliminated, thereby forming a device having optical semiconductor(s) provided therein.

Now effects of the above method of forming a device having an optical semiconductor element disposed therein are illustrated. FIG. 6 schematically illustrates terminal connecting structure of the head portion of the embodiment and conventional technology respectively. FIG. 6(a) shows terminal connection structure of the conventional technology, while FIG. 6(d) shows a corresponding circuit diagram. The terminals 24a, 24b, 25a and 25b are all in an open state, and these terminals may be charged with electricity according to the following principle. Firstly, electric charge between the electrode 5 and electrode 7 of the resistance-welding device passes through the optical semiconductor elements 22, 23, and then is charged. The space between the electrodes 5, 7 is in a full charging state, and a voltage of 180 V is applied therebetween; however, since diameter of the head portion 2 is about 4-5 mm, a strong magnetic field of 1 Kv/cm or more may be induced. Consequently, even no contact occurs, the current still flows across nearby good conductor such as an optical semiconductor through air. Generally speaking, electric discharging in air begins when electric field is about 1 Kv/cm strong, and the electric discharging is a serious problem, which affects final product efficiency of the optical semiconductors. Furthermore, it is commonly believed that a current is induced in metal (including semiconductor) such as an optical semiconductor and wiring thereof. Specifically, when a resistance welding is running, a large transient current passes and accordingly a magnetic field is generated therearound. Affected by the magnetic field, inductive electricity is induced in the optical semiconductor and its wiring, thus making them charged with electricity.

In accordance with this viewpoint, in the embodiment, as shown in FIG. 6(b), all terminals 24a, 24b, 25a and 25b are in an electrical shorting status, and this status is represented by the circuit diagram shown in FIG. 6(e). In the drawing, thick line portion represents additionally added wiring portion. As illustrated above, the terminals 24a, 24b, 25a and 25b are electrically shorted via the connection terminal 6, and they have the same potential. In addition, the connection terminal 6 is electrically shorted via method such as welding; therefore, the resistance thereof is much smaller than that of the element. Therefore, the electric charge (buffering current) generated in respective terminals flows from the terminals to the connection terminal 6, then escapes from the head portion 2 via the solder for example the connecting portion 67 and other connection terminals 6, and finally flows through the first electrode 5. By this manner, the electric charge generated in each terminal is discharged without passing through the element, thereby preventing damage to the element.

In addition, the above embodiment is an example in which the terminals are in an open status; however, in situation that the GND end of the element is connected with the head portion (namely, the head portion serves as the GND), the terminal at one side (not the GND side) and the terminal at the GND side may be electrically shorted, thereby achieving same effect. Generally, when two terminals of the element are electrically shorted, and passing resistance is much smaller than resistance of the element, current comes from any position will not pass across the element.

By using method of the invention, the final product efficiency can be improved to 90%-99%, thus greatly reducing rate of defective products caused by welding process.

What are described are embodiments of the invention; however, the embodiments of the invention are not limited to above description. For example, instead of using a connecting portion to electrically short terminals and make charge be transferred to the head portion, as an electrical shorting manner, the connection terminal that connects respective terminals together may be grounded. Hence, since the electricity charge generated in the terminals flows into the GND through the connection terminal, electricity charge will not accumulate in the element, thus achieving the same effect.

Moreover, in situation that the device is comprised of a light-emitting element 22 and a light-receiving element 23, and it is necessary to adjust the light transmitted from the light-emitting element 22, the welding process may be performed when the light-emitting element 22 transmits light. For instance, in case that a light detector is positioned adjacent the fiber side at frontage of the optical axis of the cover body, once the light gets most intensive, the location of the cover body can be adjusted and the welding process can be performed at the same time. FIG. 6(c) shows an embodiment of the invention in consistency with the above situation. In a conventional method, the light-receiving element 23 is directly welded in an open status. Here, the same effect may also be expected if the method is applied only to the light-receiving element. In addition, the figure shows that the terminals of the light-receiving element are grounded; however, such connection terminal as those described above may also be employed, and these connection terminals may be electrically shorted from each other.

Resultantly, as a terminal shorting method, the shorting may be realized directly without usage of the connection terminals. Take an example, the terminals may be clasped by a clamp or connected together by welding manner. Furthermore, the terminals may also be inserted into corresponding holes formed in a metal body, and then electrically shorted with each other.

What is claimed is:

1. A method of forming a device having an optical semiconductor element provided therein, by bonding a cover body that can cover the optical semiconductor element, to a head portion having the optical semiconductor element, comprising the steps of:
a short circuit step of shorting terminals of the optical semiconductor with each other;
a bonding step of bonding the head portion and the cover body by welding; and
a step of eliminating short between the shorted terminals.

2. The method according to claim 1, wherein the short circuit step comprises:
a step of electrically connecting respective terminals to electrically conductive connection terminals; and
a connection terminal short circuit step of shorting the connection terminals with each other.

3. The method according to claim 2, wherein in the connection terminal short circuit step, the connection terminals are connected with each other by welding.

4. The method according to claim 2, wherein in the connection terminal short circuit step, the connection terminals are grounded.

5. The method according to claim 2, wherein the short circuit step comprises:
a step of holding the number of connection terminals, holding the head portion on a receptacle that is electrically connected with the connection terminals, and at the same time, electrically coupling a first electrode, which is electrically connected with the receptacle, to a head flange disposed at a front end of the head portion; and
a step of electrically connecting a cover flange disposed at a front end of the cover body to a second electrode; wherein
in the bonding step, the head flange and the cover flange are sealed together, and a current passes through the first and second electrodes, thus making the head flange and the cover flange welded together.

6. The method according to claim 1, wherein in the short circuit step, the terminals are held together by a clip.

7. The method according to claim 1, wherein in the short circuit step, the terminals are held together by welding.

8. The method according to claim 1, wherein in the short circuit step, the terminals are inserted into respective holes formed in a metal body, thus making the terminals shorted.

9. The method according to claim 1, wherein the optical semiconductor comprises a light-emitting element and a light-receiving element; and in the short circuit step, the terminals of the light-emitting element and light-receiving element are all shorted with each other.

10. The method according to claim 1, wherein the optical semiconductor comprises a light-emitting element and a light-receiving element; and in the short circuit step, the terminals of the light-receiving element are shorted with each other when the light-emitting element irradiates light.
